(19) United States
(12) Patent Application Publication
(10) Pub. No.: US 2022/0035455 A1
(43) Pub. Date: Feb. 3, 2022

(54) IN-PLANE VIBRATION STRUCTURE

(71) Applicant: Murata Manufacturing Co., Ltd., Nagaokakyo-shi (JP)

(72) Inventors: Jun ENDO, Nagaokakyo-shi (JP); Shozo OTERA, Nagaokakyo-shi (JP); Yutaka ISHIURA, Nagaokakyo-shi (JP)

(21) Appl. No.: 17/503,899

(22) Filed: Oct. 18, 2021

Related U.S. Application Data
(63) Continuation of application No. PCT/JP2020/039203, filed on Oct. 19, 2020.

(30) Foreign Application Priority Data
Oct. 23, 2019 (JP) 2019-192530

(51) Int. Cl. G06F 3/01; H01L 41/09; H01L 41/047

(52) U.S. Cl. CPC G06F 3/016; H01L 41/0475; H01L 41/0933

(57) ABSTRACT

An in-plane vibration structure that includes a frame-shaped member defining an opening; a vibration portion in the opening; a beam portion connecting the frame-shaped member and the vibration portion; a piezoelectric film having a first main surface with a first electrode and a second main surface with a second electrode; a first support portion connecting the frame-shaped member and the first main surface; a second support portion connecting the vibration portion and the first main surface; a wiring member that has wiring for applying a voltage to the first electrode and the second electrode and is in contact with the first main surface at a predetermined contact portion; a first conductive member disposed between the first support portion and the contact portion in a plan view, and connecting the first electrode and the wiring; and a second conductive member connecting the second electrode and the wiring.

### CROSS REFERENCE TO RELATED APPLICATIONS

The present application is a continuation of International application No. PCT/JP2020/039203, filed Oct. 19, 2020, which claims priority to Japanese Patent Application No. 2019-192530, filed Oct. 23, 2019, the entire contents of each of which are incorporated herein by reference.

### FIELD OF THE INVENTION

The present invention relates to an in-plane vibration structure that vibrates in a plane direction.

### BACKGROUND OF THE INVENTION

In recent years, in an input device such as a touch panel, a tactile presentation device has been used. The tactile presentation device provides tactile feedback to a user by transmitting vibration in response to the user performing a pressing operation.

For example, Patent Document 1 proposes a tactile presentation device that gives tactile feedback to a user by using a piezoelectric film. The piezoelectric film includes a first electrode and a second electrode on a first main surface and a second main surface, respectively. The piezoelectric film expands and contracts in a plane direction in response to a voltage being applied to the electrodes on the first main surface and the second main surface. A vibration portion vibrates in the plane direction due to the expansion and contraction of the piezoelectric film.

Patent Document 1: International Publication No. 2019/013164

### SUMMARY OF THE INVENTION

In order to apply the voltage to the piezoelectric film, it is necessary to connect a conductive member to the first electrode and the second electrode. However, since the piezoelectric film expands and contracts, a mechanical load is applied to the conductive member and can cause failure at the connection with the electrodes.

Thus, an object of the present invention is to provide an in-plane vibration structure that reduces a mechanical load generated on a conductive member.

An in-plane vibration structure according to an aspect of the present invention includes a frame-shaped member defining an opening; a vibration portion in the opening; a beam portion connecting the frame-shaped member and the vibration portion; a piezoelectric film that has a first main surface with a first electrode and a second main surface with a second electrode, the piezoelectric film vibrating in a plane direction in response to a voltage being applied to the first electrode and the second electrode; a first support portion connecting the frame-shaped member and the first main surface of the piezoelectric film; a second support portion connecting the vibration portion and the first main surface of the piezoelectric film; a wiring member that has wiring for applying the voltage to the first electrode and the second electrode, the wiring member in contact with the first main surface of the piezoelectric film at a predetermined contact portion; a first conductive member disposed between the first support portion and the contact portion in a plan view of the in-plane vibration structure and connecting the first electrode and the wiring; and a second conductive member connecting the second electrode and the wiring.

The piezoelectric film is pressed against the wiring member at the contact portion. The amount of expansion and contraction of the piezoelectric film is different between areas divided at the contact portion. In the piezoelectric film, the amount of expansion and contraction of the area between the contact portion and the first support portion is smaller than the amount of expansion and contraction of the area between the contact portion and the second support portion. Accordingly, the amount of expansion and contraction is relatively small at the position where the conductive member is disposed, and the mechanical load is reduced.

According to the present invention, the mechanical load generated on the conductive member can be reduced.

### EXPLANATION OF THE DRAWINGS

FIG. 1 is a perspective view illustrating a configuration of a vibration structure 1.

FIG. 2(A) is a plan view of the vibration structure 1, and FIG. 2(B) is a sectional view taken along a line I-I illustrated in FIG. 2(A).

FIG. 3 is a schematic sectional view illustrating a structure of a piezoelectric element 11.

FIG. 4(A) is a sectional view, as a reference diagram, of the piezoelectric element 11 when a conductive double-sided adhesive 56 is disposed on a side close to a first end 111, and FIG. 4(B) is a bottom view of the piezoelectric element 11.

FIG. 5 is an enlarged sectional view of the piezoelectric element 11 and an FPC (Flexible printed circuit) 58.

### DETAILED DESCRIPTION OF THE INVENTION

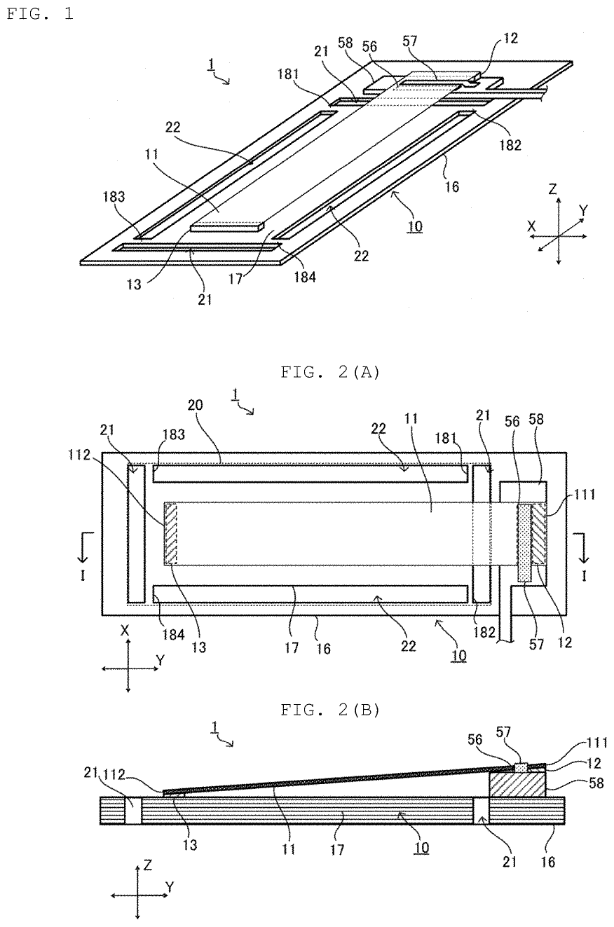

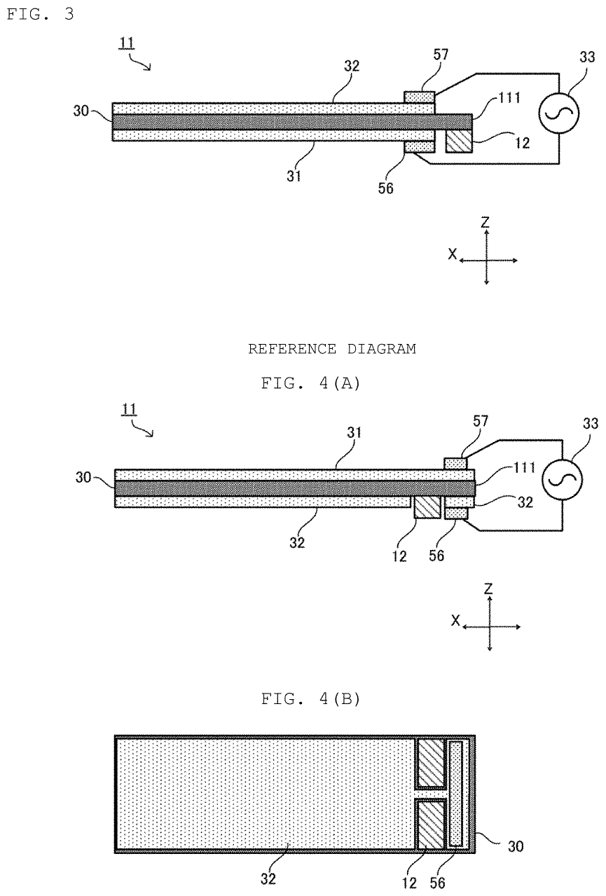

FIG. 1 is a perspective view illustrating a configuration of a vibration structure 1. FIG. 2(A) is a plan view of the vibration structure 1, and FIG. 2(B) is a sectional view taken along a line I-I illustrated in FIG. 2(C). FIGS. 1 and 2(A) are views seen through a protective film and a piezoelectric film 30 (see FIG. 3). In the present embodiment, a lateral direction of the vibration structure 1 is referred to as an X-axis direction, a longitudinal direction of the vibration structure 1 is referred to as a Y-axis direction, and a thickness direction is referred to as a Z-axis direction.

The vibration structure 1 includes a base 10, a piezoelectric element 11, a double-sided tape 12, a double-sided tape 13, a conductive double-sided adhesive 56, a conductive single-sided adhesive 57, and an FPC (Flexible printed circuit) 58. The base 10 has a frame-shaped member 16, a vibration portion 17, and a beam portion. The beam portion has four portions: a beam portion 181, a beam portion 182, a beam portion 183, and a beam portion 184.

The frame-shaped member 16 has a rectangular shape in plan view. The frame-shaped member 16 has a shape defining an opening 20 having a rectangular shape. The vibration portion 17, the beam portion 181, the beam portion 182, the beam portion 183, and the beam portion 184 are arranged in the opening 20.

The vibration portion 17 has a rectangular shape in plan view. The area of the vibration portion 17 is smaller than the area of the opening 20. The vibration portion 17 is supported by the frame-shaped member 16 at four corner portions by the beam portion 181, the beam portion 182, the beam portion 183, and the beam portion 184. The beam portion 181, the beam portion 182, the beam portion 183, and the beam portion 184 each have a long rectangular shape along the X-axis direction. The beam portion 181, the beam portion 182, the beam portion 183, and the beam portion 184 hold the vibration portion 17 at both end portions of the vibration portion 17 in the Y-axis direction. First openings 21 and second openings 22 are defined by the frame-shaped member 16, the vibration portion 17, the beam portion 181, the beam portion 182, the beam portion 183, and the beam portion 184.

The first openings 21 are arranged on sides close to both ends of the frame-shaped member 16 in the Y-axis direction which is the longitudinal direction of the frame-shaped member 16. The second openings 22 are arranged on sides close to both the ends of the frame-shaped member 16 in the X-axis direction which is the lateral direction of the frame-shaped member 16. The first opening 21 has a long rectangular shape along the X-axis direction. The second opening 22 has a long rectangular shape along the Y-axis direction.

The frame-shaped member 16, the vibration portion 17, and the beam portions 181, 182, 183, and 184 are made of the same material (for example, acrylic resin, PET, polycarbonate, glass epoxy, FRP, metal, glass, or the like). The frame-shaped member 16, the vibration portion 17, and the beam portion 18 are preferably made of stainless steel (SUS). SUS has excellent workability and durability, and has appropriate rigidity. SUS may be insulated by being coated with resin such as polyimide if necessary.

The frame-shaped member 16, the vibration portion 17, and the beam portions 181, 182, 183, and 184 are formed by punching one plate member having a rectangular shape along the shapes of the first openings 21 and the second openings 22. The frame-shaped member 16, the vibration portion 17, and the beam portions 181, 182, 183, and 184 may be separate members, but can be easily manufactured by punching a single member. Since the frame-shaped member 16, the vibration portion 17, and the beam portions 181, 182, 183, and 184 are parts of a same material, it is not necessary to use another material (a material with creep deterioration) such as a rubber material in order to support the vibration portion 17, and it is possible to stably hold the vibration portion 17 for a long period of time.

It is preferable that a thickness of the base 10 is 0.1 mm to 3 mm. When the thickness of the base 10 is 0.1 mm to 3 mm, since the base 10 has appropriate rigidity, it is possible to prevent the entire base 10 from being plastically deformed by the vibration of the vibration portion 17, and it is possible to reduce the thickness of the vibration structure 1.

The piezoelectric element 11 is connected to a first main surface of the base 10. A first end 111 of the piezoelectric element 11 in the Y-axis direction is connected to the frame-shaped member 16. More specifically, the first end 111 is connected to the frame-shaped member 16 with the double-sided tape 12 and the FPC 58 interposed therebetween. A second end 112 of the piezoelectric element 11 in the Y-axis direction is connected to the vibration portion 17 with the double-sided tape 13 interposed therebetween. The double-sided tape 12 and the double-sided tape 13 each have a long rectangular shape along the X-axis direction in plan view. Widths of the double-sided tape 12 and the double-sided tape 13 are substantially the same as a width of the piezoelectric element 11. The double-sided tape 12 and the double-sided tape 13 are made of an insulating adhesive material. The double-sided tape 12 is an example of a “first support portion” of the present description, and the double-sided tape 13 is an example of a “second support portion” of the present description.

FIG. 3 is a schematic sectional view illustrating a structure of the piezoelectric element 11. The piezoelectric element 11 includes the piezoelectric film 30, a first electrode 31, and a second electrode 32. In the piezoelectric film 30, the first electrode 31 is formed on a first main surface and the second electrode 32 is formed on a second main surface. The first electrode 31 and the second electrode 32 are formed on the piezoelectric film 30 by, for example, a vapor deposition method. The piezoelectric film 30 has a long rectangular shape along the Y-axis direction which is the longitudinal direction of the frame-shaped member 16 in plan view.

The first electrode 31 and the second electrode 32 are substantially entirely formed on the respective main surfaces of the piezoelectric film 30 except for a part close to the first end 111. The double-sided tape 12 is connected to the first main surface at a portion on which the electrodes are not formed. The double-sided tape 12 is connected to an upper surface of the FPC 58.

The conductive double-sided adhesive 56 is connected to an end portion of the first electrode 31 close to the first end 111. The conductive double-sided adhesive 56 is an example of a first conductive member. The conductive single-sided adhesive 57 is connected to an end portion of the second electrode 32 close to the first end 111. The conductive single-sided adhesive 57 is an example of a second conductive member. The conductive double-sided adhesive 56 is connected to a first wire (not illustrated) formed on the upper surface of the FPC 58. The conductive single-sided adhesive 57 is connected to a second wire (not illustrated) formed on the upper surface of the FPC 58. The FPC 58 is an example of a wiring member having wiring for applying a voltage to the first electrode 31 and the second electrode 32. Accordingly, the first electrode 31 and the second electrode 32 are both connected to a power supply 33.

When the power supply 33 applies an AC voltage to the first electrode 31 and the second electrode 32, the piezoelectric film 30 expands and contracts along the Y-axis direction. When the piezoelectric film 30 expands and contracts along the Y-axis direction, the vibration portion 17 vibrates in a plane direction along the Y-axis direction. The piezoelectric film 30 is connected to the vibration portion 17 on a side close to the second end 112 and pulls the vibration portion 17 toward the first end 111. In the vibration structure 1 of the present embodiment, the vibration portion 17 can be resonated when a frequency of the AC voltage applied to the piezoelectric film 30 is set according to a resonance frequency of the vibration portion, and thus the vibration portion 17 can be vibrated efficiently.

The vibration structure 1 of the present embodiment can be used for a tactile presentation device. The tactile presentation device includes a touch panel (not illustrated) for detecting a touch operation, and the vibration structure 1. When the touch panel (not illustrated) detects a touch operation of a user, a drive circuit (not illustrated) drives the power supply 33 and applies the AC voltage to the piezoelectric film 30. Accordingly, when the user performs a touch operation, the vibration structure 1 can give tactile feedback through the vibration portion 17.

The piezoelectric film 30 is made of, for example, polyvinylidene fluoride (PVDF). The piezoelectric film 30 may be made of a chiral polymer. The chiral polymer includes polylactic acid. The polylactic acid includes poly-L-lactide (PLLA) or poly-D-lactide (PDLA).

When PVDF is used for the piezoelectric film 30, since PVDF is water resistant, an electronic device including the vibration structure 1 in this example can be vibrated in the same manner in any humidity environment.

When the polylactic acid is used for the piezoelectric film 30, since the polylactic acid is a highly permeable material, an internal state of the device can be visually recognized as long as the electrode and the vibration portion 17 added to the polylactic acid are transparent materials, and thus, it becomes easy to manufacture the device. Moreover, since the polylactic acid is not pyroelectric, the electronic device can be vibrated in the same manner in any temperature environment. For example, when the vibration structure 1 is touched by a human hand and body heat is transferred to the piezoelectric film 30, the characteristics of the piezoelectric film 30 do not change. Thus, it is preferable that the polylactic acid is used as the piezoelectric film 30 of the electronic device that is touched by a human hand. In the case of the polylactic acid, the piezoelectric film 30 can be expanded and contracted along the Y-axis direction by the piezoelectric film being cut such that each portion of the outer periphery is approximately 45° with respect to an expansion and contraction direction.

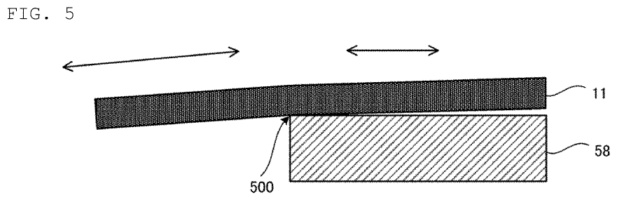

As illustrated in FIG. 3, the double-sided tape 12 is disposed on a side of the piezoelectric film 30 close to the first end 111, and the conductive double-sided adhesive 56 is disposed on a side of the double-sided tape 12 close to the second end 112. FIG. 4(A) is a sectional view of the piezoelectric element 11 when the conductive double-sided adhesive 56 is disposed on the side close to the first end 111 as a reference diagram. FIG. 4(B) is a bottom view of the piezoelectric element 11.

Since the first electrode 31 is made of metal, when the first electrode 31 is formed on the entire surface, there is a possibility that the double-sided tape 12 does not stick to the first electrode 31 or adhesiveness of the double-sided tape 12 decreases. Since a high mechanical load is generated on the double-sided tape 12 when the vibration portion 17 vibrates, there is a concern that the first electrode 31 peels off. Accordingly, it is preferable that the double-sided tape 12 is directly attached to the piezoelectric film 30 instead of to the first electrode 31 made of metal.

Thus, as illustrated in FIGS. 4(A) and 4(B), if the conductive double-sided adhesive 56 is disposed on the side close to the first end 111, it is necessary to form the first electrode 31 at a location other than a location where the double-sided tape 12 is attached. In this case, it is necessary to pattern the first electrode 31. Since part of the first electrode 31 becomes very thin, there is a concern about disconnection when the vibration portion 17 vibrates.

Thus, in the vibration structure 1 of the present embodiment, the double-sided tape 12 is disposed on the side of the piezoelectric film 30 close to the first end 111, and the conductive double-sided adhesive 56 is disposed on the side of the double-sided tape 12 close to the second end 112. Accordingly, it is not necessary to pattern the first electrode 31, and it is possible to prevent disconnection of the first electrode 31.

As illustrated in FIG. 2(B), the piezoelectric element 11 is connected to the frame-shaped member 16 on the side close to the first end 111 with the double-sided tape 12 and the FPC 58 interposed therebetween, and is connected to the vibration portion 17 on the side close to the second end 112 with the double-sided tape 13 interposed therebetween. Accordingly, the piezoelectric element 11 is connected to the double-sided tape 12 at a position higher than that of the double-sided tape 13 due to the thickness of the FPC 58, that is, the piezoelectric element is disposed at an angle. Accordingly, since the piezoelectric element 11 and the vibration portion 17 are separated from each other, the first electrode 31 and the vibration portion 17 are not in contact with each other. Therefore, the first electrode 31 and the vibration portion 17 are not short-circuited.

FIG. 5 is an enlarged sectional view of the piezoelectric element 11 and the FPC 58. As illustrated in FIG. 5, since the piezoelectric element 11 is disposed at an angle, part of the first main surface of the piezoelectric element is in contact with part of the FPC 58. The piezoelectric element 11 is in contact with a corner portion 500 of the FPC 58 illustrated in FIG. 5, and is pressed against the FPC 58. That is, the conductive double-sided adhesive 56 is disposed between the double-sided tape 12 and the contact portion 500 in plan view.

The piezoelectric element 11 expands and contracts along the Y-axis direction at a location where the first electrode 31 and the second electrode 32 are formed. The area of the piezoelectric element 11 between the second end 112 of the piezoelectric element 11 and the contact portion 500 expands and contracts greatly in response to the resonance of the vibration portion 17. On the other hand, since the piezoelectric element 11 is pressed against the contact portion 500, the amount of expansion and contraction is relatively small in the area of the piezoelectric element 11 between the first end 111 of the piezoelectric element 11 and the contact portion 500. That is, the conductive double-sided adhesive 56 is connected to the first main surface at a location where the amount of expansion and contraction is small. Accordingly, the mechanical load generated on the conductive double-sided adhesive 56 is reduced.

The piezoelectric element 11 may be connected to the FPC 58 at the contact portion 500 by an adhesive or the like. In this case, the area of the piezoelectric element 11 between the first end 111 of the piezoelectric element 11 and the contact portion 500 is not affected by the resonance of the vibration portion 17.

In the present embodiment, the conductive single-sided adhesive 57 is also disposed between the double-sided tape 12 and the contact portion 500 in plan view. Since the conductive single-sided adhesive 57 is disposed on a side close to the upper surface, the mechanical load on the conductive single-sided adhesive 57 is lower than that on the conductive double-sided adhesive 56. Thus, it is not essential that the conductive single-sided adhesive 57 is disposed between the double-sided tape 12 and the contact portion 500 in plan view.

It is preferable that the first wire of the FPC 58 is provided at a position where the conductive double-sided adhesive 56 is disposed. Since the first wire and the first electrode 31 have the same potential, the first wire and the first electrode 31 may be in contact with each other at the contact portion 500. However, in order to protect the first wire, it is preferable that the contact portion 500 is disposed at a position covered with the insulating material of the FPC 58.

The conductive single-sided adhesive 57 is connected to the piezoelectric element 11 at a position overlapping the piezoelectric element 11 in plan view, and is connected to the second wire at a position not overlapping the piezoelectric element 11 in plan view.

Finally, the description of the aforementioned embodiment is illustrative in all respects, and should not be considered as limiting. The scope of the present invention is defined by the claims rather than by the aforementioned embodiment. The scope of the present invention is intended to include all changes within the meaning and scope equivalent to the claims.

### DESCRIPTION OF REFERENCE SYMBOLS

1: Vibration structure

10: Base

11: Piezoelectric element

12, 13: Double-sided tape

14: Protective film

16: Frame-shaped member

17: Vibration portion

18: Beam portion

20: Opening

21: First opening

22: Second opening

30: Piezoelectric film

31: First electrode

32: Second electrode

33: Power supply

56: Conductive double-sided adhesive

57: Conductive single-sided adhesive

58: FPC

111: First end

112: Second end

181, 182, 183, 184: Beam portion

500: Contact portion

1. An in-plane vibration structure comprising:
a frame-shaped member defining an opening;
a vibration portion in the opening;
a beam portion connecting the frame-shaped member and the vibration portion;
a piezoelectric film having a first main surface and a second main surface;
a first electrode on the first main surface of the piezoelectric film and a second electrode on the first main surface of the piezoelectric film, the piezoelectric film configured to vibrate in a plane direction in response to a voltage being applied to the first electrode and the second electrode;
a first support portion connecting the frame-shaped member and the first main surface of the piezoelectric film;
a second support portion connecting the vibration portion and the first main surface of the piezoelectric film;
a wiring member that has wiring for applying the voltage to the first electrode and the second electrode, the wiring member in contact with the first main surface of the piezoelectric film at a predetermined contact portion;
a first conductive member disposed between the first support portion and the contact portion in a plan view of the in-plane vibration structure and connecting the first electrode and the wiring; and
a second conductive member connecting the second electrode and the wiring.

2. The in-plane vibration structure according to claim 1, wherein the second conductive member is disposed between the first support portion and the contact portion in the plan view.

3. The in-plane vibration structure according to claim 2, wherein the first main surface of the piezoelectric film and the wiring member are connected at the contact portion.

4. The in-plane vibration structure according to claim 1, wherein the first main surface of the piezoelectric film and the wiring member are connected at the contact portion.

5. The in-plane vibration structure according to claim 1, wherein
the wiring of the wiring member includes a first wire connected to the first conductive member, a second wire connected to the second conductive member, and an insulating material covering the first wire and the second wire, and
the contact portion at the insulating material.

6. The in-plane vibration structure according to claim 1, wherein
the first conductive member is a conductive double-sided adhesive and is connected to the piezoelectric film and the wiring member at a position overlapping the piezoelectric film in the plan view, and
the second conductive member is a conductive single-sided adhesive, is connected to the piezoelectric film at a position overlapping the piezoelectric film in the plan view, and is connected to the wiring member at a position not overlapping the piezoelectric film in the plan view.

7. The in-plane vibration structure according to claim 1, wherein the piezoelectric film is connected to the first support portion at a position higher than the second support portion in the plan view.

8. The in-plane vibration structure according to claim 1, wherein the piezoelectric film comprises PVDF or PLLA.

9. The in-plane vibration structure according to claim 1, wherein the first support portion and the second support portion are double-sided tape.

10. The in-plane vibration structure according to claim 1, wherein the first conductive member is disposed closer to the second support portion than the second conductive member.

11. The in-plane vibration structure according to claim 1, wherein the first support portion is directly attached to the first main surface of the piezoelectric film.

12. The in-plane vibration structure according to claim 11, wherein the first support portion connects the frame-shaped member and the first main surface of the piezoelectric film via the wiring member.

13. The in-plane vibration structure according to claim 1, wherein the first support portion connects the frame-shaped member and the first main surface of the piezoelectric film via the wiring member.
